(19) United States
(12) Patent Application Publication
(10) Pub. No.: US 2003/0045081 A1
(43) Pub. Date: Mar. 6, 2003

(54) MOSFET having a stacked silicon structure and method

(75) Inventors: Kuan-Ting Lin, Keelung (TW); Shih-Che Lin, Keelung (TW)

Correspondence Address: Janah & Associates, P.C., Suite 106, 650 Delancey Street, San Francisco, CA, 94107-2001, US

(73) Assignee: Applied Materials, Inc.

(21) Appl. No.: 10/183,131

(22) Filed: Jun. 25, 2002

(30) Foreign Application Priority Data
Aug. 30, 2001 (TW) 090121520

(51) Int. Cl. H01L 21/3205; H01L 21/4763

(52) U.S. Cl. 438/592; 438/508

(57) ABSTRACT

A stacked silicon gate structure for a MOSFET may be formed in a CVD chamber. The stacked structure includes a first polycrystalline silicon layer, a microcrystalline layer, and second polycrystalline silicon layer. The microcrystalline layer has a randomly orientated crystal structure with a smaller average crystal grain size than the first and second polycrystalline silicon layers. The microcrystalline layer is capable of maintaining its original crystal structure even while undergoing high temperature process substantially without further recrystallization. This allows the microcrystalline layer to suppress migration of dopants in the second polycrystalline silicon layer into the first polycrystalline silicon layer and thereby prevent a shift in the threshold voltage that would otherwise result from such dopant penetration.

### BACKGROUND

The present invention relates to a semiconductor device structure and a method of manufacture thereof.

Integrated circuits and displays can have thousands or even millions of devices in a specific area of a substrate, such as a semiconducting silicon wafer or dielectric panel. Electrically connecting structures are used to connect these devices to each other and to the external environment. One such device, a metal oxide semiconductor field effect transistor (MOSFET), is widely used in the fabrication of semiconducting integrated circuits. A MOSFET is manufactured by forming an undoped polycrystalline silicon layer, commonly known as a polysilicon layer, over a relatively thin silicon oxide layer. The polycrystalline silicon layer and the silicon oxide layer are then patterned to form a gate conductor on a gate oxide with source and drain regions adjacent to, and on opposite sides of, the gate conductor. The gate conductor may be used to self-align dopants implanted into the substrate on opposite sides of the gate conductor. The gate conductor and source/drain regions are then concurrently implanted with dopant species. If the dopant is an n-type dopant, then the resulting MOSFET is called an NMOSFET device (“NMOS”). Conversely, if the dopant species is p-type, then the resulting MOSFET is called a PMOSFET device (“PMOS”). Integrated circuits typically use either NMOSFET devices exclusively, PMOSFET exclusively, or a combination of both on a single substrate. The combination of an NMOSFET device and a PMOSFET device on a single substrate is termed a complementary MOSFET device.

FIG. 1 is a schematic cross-sectional view of a PMOSFET device in accordance with the prior art. A gate oxide layer 12, such as a silicon dioxide layer, is formed on a silicon substrate 10. A patterned polycrystalline silicon layer 14 having columnar crystal structure doped with p-type dopants is formed on the oxide layer 12 to serve as gate conductor. Gate sidewall spacers 16 made of silicon oxide are formed on the sidewall of the polycrystalline silicon layer 14. Light doped source/drain (LDD) regions 18 under the sidewall spacers 16 are formed by ion implantation with light dopant dose. Source/drain regions 20 are formed on opposite sides of the gate conductor by ion implantation.

In forming a PMOSFET device with a polycrystalline silicon gate conductor, the polycrystalline silicon from which the gate conductor is formed is doped with p-type dopants, such as boron species, to lower its sheet resistivity. P-type dopants are usually implanted sufficiently deep within the gate conductor to allow a substantial amount of the implanted dopant to diffuse down to the bottom of the gate conductor during subsequent heat processing. Boron species, in the form of elemental boron or boron difluoride ions, is typically used to dope the polycrystalline silicon gate to form a junction within the silicon substrate for PMOSFET devices.

However, the boron implanted into a gate conductor often migrates even further into underlying layers, such as the gate oxide layer, during the heat processing step because the diffusion rate of boron in polycrystalline silicon is relatively high. The penetration of the boron atoms into the gate oxide layer reduces the reliability of the gate oxide layer and is especially problematic when the boron atoms are implanted too deeply into the gate conductor. IN certain cases, the boron atom migration may even continue through the gate oxide layer and into the underlying channel portion in the substrate 300, as indicated by the symbol 30 in FIG. 1. The increased boron dopant concentration in the channel can result in a shift in the threshold voltage which is undesirable. Boron penetration into the channel can also cause other undesirable effects such as an increased electron trapping, decreased low-field hole mobility, and degradation of the drive current. Boron penetration can futher cause polycrystalline silicon depletion when boron migrating from the lower portions of the gate conductor as a result of uncontrolled channel doping leaves the lower portion of the gate conductor with less than an optimal dopant concentration.

In one method of attempting to solve the boron migration and penetration problem, an amorphous silicon layer is used as a boron diffusion barrier layer between the polycrystalline layers. The amorphous layer is non-crystalline and is composed of a glassy-type phase having little or no long range order of the molecules of the layer such as that present in crystalline materials. However, one problem with the amorphous silicon layer is that it crystallizes into columnar polycrystalline silicon having large grain sizes upon sufficient heat exposure. As such, the amorphous silicon layer does not sufficiently suppress boron penetration when used for stacked structures where some heat treatment may be needed in subsequent processing steps.

Therefore, it is desirable to develop have a MOSFET structure in which penetration and migration of the dopant is controlled. It is also desirable to have a technique for fabricating MOSFET devices, such as PMOSFET devices that are doped with boron, to reduce boron penetration and polycrystalline silicon depletion.

### SUMMARY

A stacked silicon gate structure for a MOSFET comprises a semiconductor and a dielectric layer on the semiconductor. There are first and second polycrystalline silicon layers over the dielectric layer, at least one of the polycrystalline silicon layers being doped with a dopant. A microcrystalline layer is provided between the first and second polycrystalline layers. The microcrystalline layer has an average grain size that is smaller than an average grain size of the first and second polycrystalline silicon layers.

In a method of forming a stacked silicon structure for a MOSFET, a dielectric layer is formed on a semiconductor substrate. On the dielectric layer, first and second polycrystalline silicon layers are formed with a microcrystalline silicon layer therebetween, the microcrystalline silicon layer having average grain size that is smaller than an average grain size of the first and second polycrystalline silicon layers. The resulting first and second polycrystalline silicon layers, microcrystalline layer, and dielectric layer are patterned. And the second polycrystalline silicon layer is doped with a p-type dopant.

In a chemical vapor deposition method comprises, a substrate is placed in a chamber and the substrate is heated. A first polycrystalline silicon layer is formed on the substrate by providing, into the chamber, a process gas comprising a silane gas. A microcrystalline silicon layer is formed on the first polycrystalline silicon layer by providing, into the chamber, a process gas comprising a hydrogen gas and a silane gas. A second polycrystalline silicon layer is formed on the microcrystalline silicon layer by providing, into the chamber, a process gas comprising a silane gas.

A stacked silicon gate structure for a PMOSFET comprises a semiconductor, a dielectric layer on the semiconductor, a first polycrystalline silicon layer on the dielectric layer, and a microcrystalline silicon layer on the first polycrystalline layer. There is a second polycrystalline silicon layer on the microcrystalline silicon layer, the second polycrystalline silicon layer being doped with a p-type dopant. The microcrystalline silicon layer comprises an average grain size that is smaller than an average grain size of the first and second polycrystalline silicon layers, whereby the microcrystalline silicon layer suppresses the migration of the p-type dopant from the second polycrystalline silicon layer.

In a chemical vapor deposition method, a substrate is placed in a chamber. The substrate is heated to a temperature of from about 500 to about 1000° C. Silane is introduced into the chamber, whereby a first polycrystalline silicon layer is formed on the substrate. Hydrogen and silane are introduced into the chamber, whereby a microcrystalline silicon layer is formed on the first polycrystalline silicon layer. The introduction of hydrogen is stopped while still continuing to introduce the silane into the chamber, whereby a second polycrystalline silicon layer is formed on the microcrystalline silicon layer.

### DRAWINGS

The foregoing aspects and the advantages of the invention will be more readily appreciated as the same becomes better understood by reference to the following detailed description, when taken in conjunction with the accompanying drawings, wherein:

FIG. 1 (prior art) is a schematic cross-sectional view of a conventional PMOSFET structure having a polycrystalline layer doped with boron showing penetration of the boron into the underlying gate oxide layer and the silicon substrate;

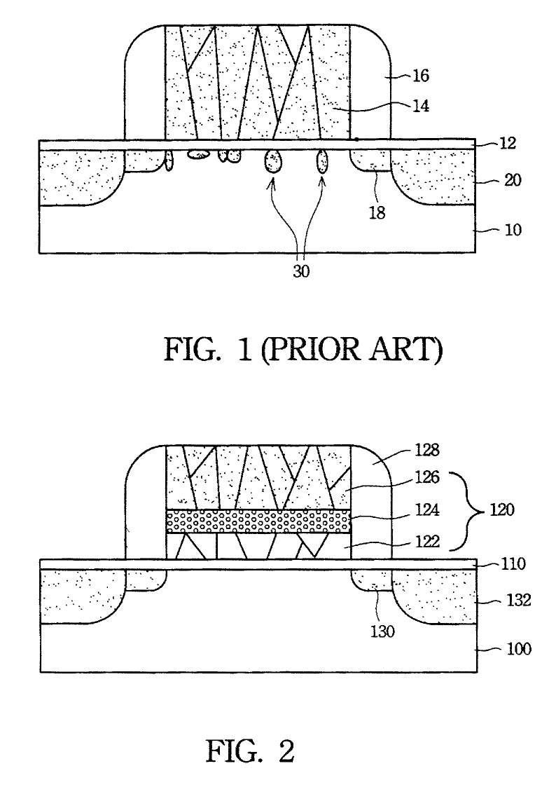

FIG. 2 is a schematic cross-sectional view of a PMOSFET structure having a stacked silicon gate structure on a silicon substrate, according to an embodiment of the structure of the present invention; and

FIGS. 3A to 3C are schematic cross-sectional views illustrating a process of fabricating the PMOSFET structure shown in FIG. 2 according to an embodiment of the process of the present invention.

### DESCRIPTION

A stacked layer structure may be used in a MOSFET transistor and is especially useful for p-type metal oxide semiconductor field effect transistors (PMOSFET). Generally, the stacked silicon structure is formed on a semiconductor such as a semiconducting silicon wafer. The stacked structure further comprises a dielectric layer on the semiconductor. First and second polycrystalline silicon layers are formed over the dielectric layer, at least one of the polycrystalline silicon layers being doped with a dopant. At least one microcrystalline layer is formed between the first and second polycrystalline layers.

The microcrystalline layer typically has grains that are crystallites, and that have a smaller average grain size than the average grain size of abutting or adjacent layers. For example, the microcrystalline layer can have an average grain size that is smaller than an average grain size of the first and second polycrystalline silicon layers. In addition, the grains of the microcrystalline layer may also be randomly oriented without a preferred crystalline orientation or order. The microcrystalline layer suppresses and blocks the migration of dopant species through the polycrystalline layers, especially when the stacked layer structure is subjected to elevated temperatures, for example, during processing of the structure.

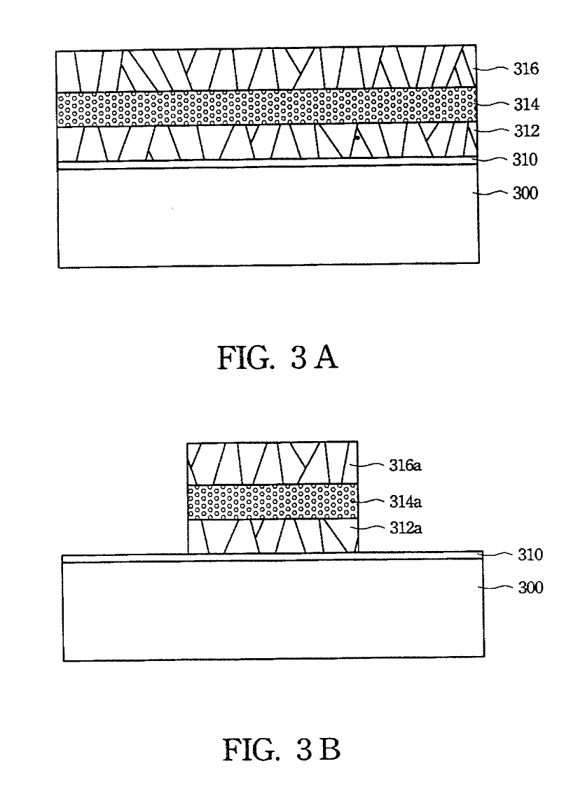

In one version, the microcrystalline layer comprises silicon and is formed under a doped polycrystalline silicon layer to suppress the migration and penetration of the dopant from the doped polycrystalline silicon layer into underlying layers or the silicon substrate. For example, FIG. 2 shows a PMOSFET structure constructed over on a semiconductor substrate 100, such as a p-type doped silicon substrate having crystalline grains with a <100>miller indices orientation. The PMOSFET structure is formed on an n-well region (not shown) of the semiconductor substrate 100. Generally, the PMOSFET structure comprises a gate dielectric layer 110 on an active area of the substrate 100, a gate conductive layer 120 on or over the gate dielectric layer 120, and source/drain regions 132 adjacent to and on opposite sides of the gate conductive layer 120. The gate dielectric layer 110 may be silicon dioxide, silicon nitride, tantalum oxide, or other such materials with high dielectric constant. Gate spacers 128 may also be formed on the sidewall of the gate conductive layer 120 to protect the gate, and suitable gate spacers 128 may be made from silicon oxide. In addition, in the source/drain regions 132, light doped source/drain regions 130 can be formed to eliminate short channel and hot electron effects that may result from narrowing of the critical dimensions.

The gate conductive layer 120 comprises a sequential stack comprising a microcrystalline silicon layer 124 abutting at least one doped polycrystalline silicon layer 126 to provide a desirable stacked crystal structure over the dielectric layer 110. Optionally, another polycrystalline silicon layer 122 may also be used on the opposing side of the monocrystalline silicon layer 124 to form a gate conductive layer 120 over the dielectric layer 100 that comprises a sequential stack of a first polycrystalline silicon layer 122, a microcrystalline silicon layer 124, and a second polycrystalline silicon layer 126. The first polycrystalline silicon layer 122 is undoped and the second polycrystalline silicon layer 126 is doped with a p-type dopant, such as boron in the form of boron or boron difluoride ions. The second polycrystalline silicon layer 126 has substantially the same crystalline structure as the first polycrystalline silicon layer 122. Both the layers 122, 126 have grains that are oriented relative to one another and can even have a preferred orientation. Typically, the grains of the polycrystalline silicon layers 122, 126 have a columnar structure. The columnar structure typically has grains shaped as vertical columns that extend outwardly from the substrate.

The microcrystalline silicon layer 124 comprises silicon grains having an average grain size that is smaller than an average grain size of the first and second polycrystalline silicon layers 122, 126. The grains can also have a random orientation in which they are adjacent grains are not oriented along a preferred direction. The microcrystalline silicon layer 124 with the small randomly oriented grains suppresses the passage of dopant migrating from the second polycrystalline silicon layer 126 into the first polycrystalline silicon layer 122, and thereby prevents penetration of the dopant into the underlying gate oxide layer 110 and the further underlying channel portion of the substrate 100 even during subsequent processes which may be conducted at elevated temperatures. In one version, the grains of the microcrystalline layer have an average size of less than about 80 Å root-mean-squared (RMS) when the the grains of the first and second polycrystalline layers have an average size of at least about 200 Å (RMS).

The microcrystalline silicon layer 124 should be sufficiently thick to suppress such boron penetration. Thus, the thickness of the microcrystalline silicon layer 124 depends on both the degree of microcrystallinity of the layer and temperature that the structure may be subjected to in further processing. Preferably, the grains of the microcrystalline layer should maintain their sizes of less than about 80 Å (RMS) even after exposure to temperatures of at least about 500° C.

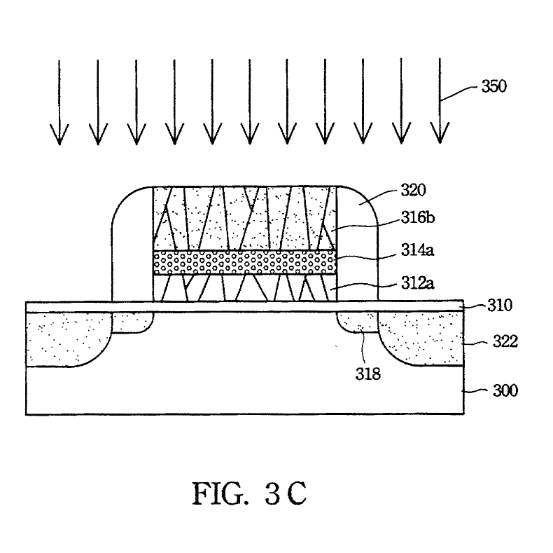

An exemplary method of fabricating such a PMOSFET structure will now be described referring to FIGS. 2 and 3A to 3C. Initially, a semiconductor substrate 300 corresponding to the semiconductor substrate 100 of FIG. 2 is provided as shown in FIG. 3A. A dielectric layer 310, made of silicon oxide, silicon nitride, tantalum oxide or other such good dielectric constant materials, is formed on the substrate 300. For example, a preferred silicon oxide dielectric layer 310 having desirable dielectric properties may be made by a conventional rapid thermal oxide fabrication method.

A first polycrystalline silicon layer 312, a microcrystalline silicon layer 314 and a second polycrystalline silicon layer 316 are subsequently formed on the dielectric layer 310. The stacked silicon layers 312, 314 and 316 can be formed by chemical vapor deposition (CVD). In one embodiment, the stacked silicon layers 312, 314 and 316 are formed by a low-pressure chemical vapor deposition (LPCVD) process in a single process chamber. The ability to perform the processes for the deposition of all of the different stacked layers in a single chamber can substantially increase process throughput. Also, use of a single chamber reduces the possiblity of contamination of the substrate when transfering the substrate from one chamber to another.

In the process, a substrate 300 is loaded into the LPCVD chamber and maintained at desirable temperatures. A process gas comprising a silicon-containing precursor, such as silane gas (SiH₄), is introduced into the chamber. A carrier gas, such as nitrogen gas (N₂), may also be optionally added to the process gas and injected into the chamber. In one version of the process, the process gas is maintained at pressures of from about 200 to about 400 Torr and the substrate is maintained at a temperature of from 695 to about 800° C. to deposit a first polycrystalline silicon layer 312 on the substrate 300 from the silane gas. The deposited polycrystalline silicon layer 312 has relatively large grains with a columnar structure.

To form a microcrystalline silicon layer 314 on the substrate 300, a hydrogen gas (H₂) is also added to the process gas while the process gas comprising the silicon-containing precursor is being continuously introduced into the chamber. A suitable addition of hydrogen gas to the process gas comprises a volumetric flow rate percentage of about 3 to about 60% of the total process gas volumetric flow rate injected into the chamber. Under the same pressure and temperature, the gases in the chamber react to form a microcrystalline silicon layer as shown in FIG. 3A. The as-formed microcrystalline silicon layer 314 has grains having an average grain size that is smaller than the average grain size of the polycrystalline silicon layer and the grains are also randomly oriented. These properties cause the microcrystalline layer 314 to serve as a barrier that prevents the diffusion of the dopant species or other species therethrough, especially at high temperatures. It also, advantageously, does not recrystallize at elevated temperatures into a layer having a large grain structure.

A second polycrystalline silicon layer 316 is formed on the microcrystalline layer 314 on the substrate 300 which in turn is over the first polycrystalline layer 312. The second polycrystalline silicon layer 316 may be formed using the same process or operational parameters for forming the first polycrystalline silicon layer 312 or by other methods as would be apparent to one of ordinary skill in the art.

One or more of the described silicon layer deposition processes may be performed in an LPCVD chamber, such as, for example, a PolyGen Centura chamber commercially available from Taiwan Applied Materials Company, Ltd., Taiwan, or other such chambers. While an LPCVD chamber and CVD process may be used to fabricate such layers, they may also be fabricated by other methods and apparatus which are also in the scope of the present invention.

The stacked silicon containing layers 322 as deposited on the substrate 300 may be used to form an exemplary PMOSFET structure as described herein. However, it should be understood that the PMOSFET structure can be modified as would be apparent to one of ordinary skill in the art and other MOSFET or PMOSFET structures are within the scope of the present invention. Referring to FIG. 3A, the stacked silicon layers of the first polycrystalline silicon layer 312, the microcrystalline silicon layer 314, and the second polycrystalline silicon layer 316 as formed, are patterned to form a desired gate pattern as shown in FIG. 3B, by conventional lithography and etching technologies. The patterned stacked silicon layers can be formed by the following exemplary process steps. A photoresist layer is coated on the second polycrystalline silicon layer 316. The photoresist layer is then exposed and developed to obtain desired pattern thereon. The stacked silicon layers are then anisotropically etched using the patterned photoresist layer to form a desirable shapes of etched features of the first polycrystalline silicon layer 312a, the microcrystalline silicon layer 314a, and the second polycrystalline silicon layer 316a.

Referring to FIG. 3C, p-type dopants, such as boron in the form of boron or boron difluoride ions, are then implanted into the substrate 300 on opposite sides of the patterned stacked silicon layers to form light doped source/drain (LDD) regions 318. A dielectric layer, such as silicon oxide layer, is formed over the substrate 300, and then etched back to form gate spacers 320 on the sidewall of the stacked silicon layers.

Dopant species are then energetically implanted into the substrate 300. P-type dopants, such as boron, at relative high kinetic energy and dose level are implanted into the substrate 300 on opposite sides of the gate spacers to form the source/drain regions 322. The p-type dopants are implanted into the second polycrystalline silicon layer 316a simultaneously to form a doped polycrystalline silicon layer 316b, corresponding to the doped polycrystalline silicon layer 128 of FIG. 2. The resulting doped polycrystalline silicon layer 316b, microcrystalline silicon layer 314a, polycrystalline silicon layer 312a and gate dielectric layer 310 compose the stacked silicon gate structure. Since the microcrystalline silicon layer 314a is formed under the doped polycrystalline silicon layer 316b, migration of the p-type dopants from the doped polycrystalline silicon layer 316b to underlying layers and other regions of the substrate 300 is limited. Thus, dopant diffusion into the first polycrystalline silicon layer 312a or substrate 300 is restricted and the boron penetration problem can be effectively reduced or even altogether prevented.

In this manner, a stacked silicon gate structure for a PMOSFET having a microcrystalline silicon layer located under a doped polycrystalline silicon layer which has small randomly orientated grains, can sufficiently suppress migration of p-type dopants, such as boron, from the doped polycrystalline silicon layer into the substrate and thereby prevent boron penetration. Advantageously, the stacked silicon layers can be formed in a single chamber thereby providing increased process throughput and reducing substrate contamination.

The present invention is described with reference to certain preferred versions thereof; however, other versions are possible. For example, the stacked semiconductor structure may be modified to other versions, such as for example, structures having different spatial orientations or shapes, as would be apparent to one of ordinary skill. Also, relative terms such as top, bottom, upper, lower, side, low, high, and other such terms, should not limit the scope of the invention, which includes variants of these terms. Therefore, the spirit and scope of the appended claims should not be limited to the description of the preferred versions contained herein.

What is claimed is:

1. A stacked silicon gate structure for a MOSFET, the structure comprising:
(a) a semiconductor;
(b) a dielectric layer on the semiconductor;
(c) first and second polycrystalline silicon layers over the dielectric layer, at least one of the polycrystalline silicon layers being doped with a dopant; and
(d) a microcrystalline layer between the first and second polycrystalline layers, the microcrystalline layer having an average grain size that is smaller than an average grain size of the first and second polycrystalline silicon layers.

2. A structure according to claim 1 wherein the second polycrystalline silicon layer is doped with a p-type dopant, and the microcrystalline layer has an average grain size that is sufficiently small to suppress migration of the p-type dopant from the second polycrystalline silicon layer into the first polycrystalline silicon layer.

3. A structure according to claim 2 wherein the p-type dopant comprises boron, the first polycrystalline silicon layer is on the microcrystalline layer, and the second polycrystalline silicon layer is on the microcrystalline layer.

4. A structure according to claim 1 wherein the microcrystalline layer comprises silicon.

5. A structure according to claim 1 wherein the grains of the first and second polycrystalline silicon layers are substantially columnar.

6. A structure according to claim 1 wherein the grains of the microcrystalline layer are substantially randomly orientated.

7. A structure according to claim 1 wherein the grains of the microcrystalline layer maintain their sizes after exposure to temperatures of at least about 500° C.

8. A structure according to claim 1 wherein the grains of the microcrystalline layer have an average size of less than about 80 Å (RMS).

9. A structure according to claim 1 wherein the grains of the first and second polycrystalline layers have an average size of at least about 200 Å (RMS).

10. A structure according to claim 1 wherein the microcrystalline layer is formed by a chemical vapor deposition process.

11. A structure according to claim 10 wherein the chemical vapor deposition process comprises forming a microcrystalline layer comprising silicon using a process gas comprising silane.

12. A structure according to claim 11 wherein the chemical vapor deposition process comprises using a process gas comprising hydrogen.

13. A method of forming a stacked silicon structure for a MOSFET, the method comprising:
(a) forming a dielectric layer on a semiconductor substrate;
(b) forming on the dielectric layer, first and second polycrystalline silicon layers with a microcrystalline silicon layer therebetween, the microcrystalline silicon layer having average grain size that is smaller than an average grain size of the first and second polycrystalline silicon layers;
(c) patterning the resulting first and second polycrystalline silicon layers, microcrystalline layer, and dielectric layer; and
(d) doping the second polycrystalline silicon layer with a p-type dopant.

14. A method according to claim 13 comprising forming the microcrystalline silicon layer to have an average grain size that is randomly oriented and sufficiently small to suppress the migration of the p-type dopant from the second polycrystalline layer to the first polycrystalline silicon layer.

15. A method according to claim 13 comprising doping the second polycrystalline silicon layer with a p-type dopant comprising boron.

16. A method according to claim 13 comprising forming the first and second polycrystalline silicon layers such that the grains of the first and second polycrystalline silicon layers are substantially columnar.

17. A method according to claim 13 comprising forming the first and second polycrystalline silicon layers by a chemical vapor deposition process using a process gas comprising silane, and forming the microcrystalline layer using a process gas comprising hydrogen and the silane.

18. A chemical vapor deposition method comprising:
(a) placing a substrate in a chamber;
(b) heating the substrate;
(c) forming a first polycrystalline silicon layer on the substrate by providing into the chamber, a process gas comprising a silane gas;
(d) forming a microcrystalline silicon layer on the first polycrystalline silicon layer by providing into the chamber, a process gas comprising a hydrogen gas and a silane gas; and
(e) forming a second polycrystalline silicon layer on the microcrystalline silicon layer by providing into the chamber, a process gas comprising a silane gas.

19. A method according to claim 18 comprising heating the substrate to a temperature of from about 695 to about 800 ° C.

20. A method according to claim 18 wherein (c) comprises forming a microcrystalline silicon layer having randomly orientated grains with a grain size that is smaller than a grain size of the first and second polycrystalline silicon layers.

21. A method according to claim 18 wherein (d) comprises providing a process gas comprising a volume percentage of hydrogen gas of from about 3 to about 60%.

22. A stacked silicon gate structure for a PMOSFET, the structure comprising:
a semiconductor;
a dielectric layer on the semiconductor;
a first polycrystalline silicon layer on the dielectric layer;
a microcrystalline silicon layer on the first polycrystalline layer; and
a second polycrystalline silicon layer on the microcrystalline silicon layer, the second polycrystalline silicon layer being doped with a p-type dopant,
wherein the microcrystalline silicon layer comprises an average grain size that is smaller than an average grain size of the first and second polycrystalline silicon layers,
whereby the microcrystalline silicon layer suppresses the migration of the p-type dopant from the second polycrystalline silicon layer.

23. A chemical vapor deposition method comprising:
(a) placing a substrate in a chamber;
(b) heating the substrate to a temperature of from about 695 to about 800° C.;
(c) introducing silane into the chamber, whereby a first polycrystalline silicon layer is formed on the substrate;
(d) introducing hydrogen and silane into the chamber, whereby a microcrystalline silicon layer is formed on the first polycrystalline silicon layer; and
(e) stopping introducing hydrogen while still continuing to introduce the silane into the chamber, whereby a second polycrystalline silicon layer is formed on the microcrystalline silicon layer.
